(19) United States
(12) Patent Application Publication
(10) Pub. No.: US 2012/0162928 A1
(43) Pub. Date: Jun. 28, 2012

(54) ELECTRONIC PACKAGE AND METHOD OF MAKING SAME

(75) Inventors: Rabindra N. Das, Vestal, NY (US); Frank D. Egitto, Binghamton, NY (US); Voya R. Markovich, Endwell, NY (US)

(73) Assignee: Endicott Interconnect Technologies, Inc., Endicott, NY (US)

(21) Appl. No.: 12/910,020

(22) Filed: Oct. 22, 2010

(51) Int. Cl. H05K 7/00; H05K 3/40; H05K 3/46

(52) U.S. Cl. 361/728; 29/846

(57) ABSTRACT

An electronic package with two circuitized substrates which sandwich an interposer therebetween, the interposer electrically interconnecting the substrates and also including an opening therein in which is positioned at least one electrical component, such as a semiconductor chip, coupled to the lower or base substrate. A second component may also be mounted on and electrically coupled to the upper surface of the top or cover circuitized substrate. A method of making such a package is also provided.

### FIELD OF THE INVENTION

This invention relates, in general, to electronics packages, one example being a chip carrier having a circuitized substrate for interconnecting a semiconductor chip coupled to the substrate to a printed circuit board (PCB), and in particular, to such circuitized substrate packages and the like for use in information handling systems (e.g., computers, telecommunications systems, etc.).

### BACKGROUND OF THE INVENTION

Electronic packages, particularly those used in chip carrier applications, have been and continue to be developed for many applications. Such a package typically comprises a circuitized substrate having a plurality of conductive and organic dielectric layers laminated together to form a multilayered structure, with the upper layer designed for redistributing electrical signals from the chip mounted on the circuitized substrate through the substrate onto a larger circuitized area so that the circuitized substrate can properly interface with the hosting circuitized substrate, typically a much larger PCB. Various earlier versions of chip carriers used ceramic as the dielectric rather than more recently developed organic materials of the type described in greater detail hereinbelow.

Generally speaking, there are two known types of such laminate organic chip carriers: those referred to as “wire-bond” chip carriers; and those referred to as “C4” (for controlled collapse chip connection) chip carriers. In both, a chip is mounted on and electrically coupled to the carrier substrate's top side (upper) circuitry. In the case of a wire-bond carrier, these connections are made using ultra thin aluminum or gold wires (also referred to by some in the industry as wire-bonds) which are bonded at one end to chip contact sites on the chip's upper surface and at the other end to wire-bond pads on the carrier substrate's upper surface circuitry. The chip is mounted on the substrate typically using a suitable adhesive. The carrier may then in turn be mounted on and electrically coupled to the PCB's upper surface circuitry using a plurality of solder balls mounted on pads on the PCB's upper surface and which form part of said circuitry. For C4 chip carriers, the chip is coupled to the carrier substrate's circuitry using solder balls, the carrier including pads for having the solder balls secured thereto. An encapsulating material may be used to surround the solder balls in the array. The carrier's pads, like those of the PCB, in turn are coupled to the carrier's substrate internal circuitry which passes through the substrate to its undersurface, where solder balls are typically used to couple the substrate to the PCB (forming a ball grid array (BGA) final package). The teachings of the present invention are adaptable to both types of chip carriers, but most preferably to those wherein the chip or chips are coupled using solder.

It is a key objective of electronic package manufacturers to produce smaller and higher density packages which are still capable of increased capacity over previous structures. Understandably, various concerns arise when attempting such miniaturization, particularly when considering that increased operational demands on such devices as semiconductor chips results in such chips operating at greater and greater temperatures. Two such concerns include potential damage due to excessive heat, and providing effective connections in such a highly dense and compact structure. To prevent package breakdown as a result of possible chip failure, providing adequate, effective heat sinking for the chip is necessary. Providing effective couplings in such tight patterns is so critical because just one connection failure may lead to an unusable end product. Both of these and other concerns must be effectively addressed in order to assure a package product which will meet today's ever-increasing demands.

The following issued U.S. patents represent various versions of electronic packages and related methods. The listing thereof is not an admission that any are prior art to the instantly claimed invention, nor that an exhaustive search has been completed. It will be understood from a reading of the present specification that the claimed invention represents a significant improvement the various packages described below and other similar packages.

In U.S. Pat. No. 5,237,743 for METHOD OF FORMING A CONDUCTIVE END PORTION ON A FLEXIBLE CIRCUIT MEMBER, issued to Busacco, et al. on Aug. 24, 1993, there is defined a method of forming conductive end portions on a flexible circuit member having a dielectric layer (e.g., polyimide) with at least one conductive element (e.g., copper) thereon. The method comprises the steps of forming (e.g., punching) an opening through both dielectric and conductive element, providing (e.g., additive plating) an electrically conducting layer on the opening's internal surface, providing (e.g., electroplating) a plurality of dendritic elements on the conducting layer's surface, and thereafter removing (e.g., punching) a portion of the dielectric and conductive element such that the formed dendritic elements (e.g., palladium) project from the flexible circuit's conductive ends.

In U.S. Pat. No. 5,278,724 for ELECTRONIC PACKAGE AND METHOD OF MAKING SAME, issued to Angulas, et al. on Jan. 11, 1994, there is described an electronic package and method of making same wherein the package includes a first circuitized substrate (e.g., PCB), a second, flexible circuitized substrate (e.g., polyimide dielectric with conductors thereon) having a semiconductor chip electrically coupled thereto. The outer portions of the flexible circuitized substrate are wrapped about the frame which in turn includes portions thereof which serve to spacedly position the wrapped flexible substrate with respect to the first substrate such that conductors on both substrates may be precisely aligned and electrically coupled in a permanent manner.

In U.S. Pat. No. 5,463,250 for SEMICONDUCTOR COMPONENT PACKAGE, issued to Nguyen, et al. on Oct. 31, 1995, there is described a package for power semiconductor components which permits thermal dissipation and current conductance. The package includes a frame assembly bonded to a substrate on which a power semiconductor chip is mounted. The frame assembly has a wire-bond grid for connecting short, uniform length wire-bonds to the surface of the chip. The grid is configured so as to have a portion overlaying and spaced from the chip a distance less than a distance required to connect a wire-bond of optimal length to each contact site of the chip. The package also uses an inner mounting pad on which the power semiconductor chip is directly mounted. The coefficient of thermal expansion of both the chip and the copper are described as being comparable. A ceramic “core” is located beneath the pad and includes a plurality of spaced copper vias capable of restricting thermal expansion.

In U.S. Pat. No. 5,530,291 for ELECTRONIC PACKAGE ASSEMBLY AND CONNECTOR FOR USE THEREWITH, issued to Chan, et al. on Jun. 25, 1996, there is described an electronic package including a base member and associated cover member designed for being positioned together to compress at least two circuitized substrates (e.g., a ceramic substrate and a plurality of flexible substrates) positioned therein. One of the substrates is substantially rigid and is positively positioned in a protected, aligned manner within the base. Additionally, the flexible substrates are precisely aligned and initially secured to the rigid substrate, the invention further using yet another resilient means to act against each of the flexible substrates when the packages fully assemble. The cover is secured to the base to effect final compression of the internal elements. This package may be positioned on and electrically coupled to another circuitized substrate.

In U.S. Pat. No. 5,616,958 for ELECTRONIC PACKAGE, issued to Laine, et al. on Apr. 1, 1997, there is described an electronic package which includes a thermally conductive, e.g., copper, member having a thin layer of dielectric material, e.g., polyimide, on at least one surface thereof. The copper thermally conductive member provides heat sinking for the chip during operation. A high density circuit pattern is provided on the polyimide and is electrically connected, e.g., using solder or wire-bonds, to the respective contact sites of a semiconductor chip. If wire-bonds are used, the copper member preferably includes an indentation therein and the chip is secured, e.g., using adhesive, within this indentation. If solder is used to couple the chip, a plurality of small diameter solder elements are connected to respective contact sites of the chip and to respective ones of the pads and/or lines of the provided circuit pattern. Significantly, the pattern possesses lines and/or pads in one portion which are of high density and lines and/or pads in another portion which are of lesser density. The chip is coupled to the higher density portion of the circuitry which then may fan out to the lesser (and larger) density lines and/or pads of the other portion of the circuitry. The resulting package is also of a thin profile configuration and particularly adapted for being positioned on and electrically coupled to a PCB or the like substrate having conductors thereon.

In U.S. Pat. No. 5,621,615 for LOW COST, HIGH THERMAL PERFORMANCE PACKAGE FOR FLIP CHIPS WITH LOW MECHANICAL STRESS ON CHIP, issued to Dawson, et al. on Apr. 15, 1997, there is described a flip chip package comprising a substrate, a ring structure attached to the substrate, a heat removal structure, and a chip thermally coupled to the heat removal structure. The package lid comprises a ring structure and a heat removal structure. The ring structure and heat removal structure are separated until after attachment of the ring structure to the substrate allowing the ring structure to be brazed to the substrate. A die attach material between the first major surface of the die and the first major surface of the heat removal structure adheres the die to and thermally couples the die to the heat removal structure. The die attach layer is of a predetermined thickness and thus provides a determined low thermal resistance making the thermal performance of the package certain.

In U.S. Pat. No. 5,710,459 for INTEGRATED CIRCUIT PACKAGE PROVIDED WITH MULTIPLE HEAT-CONDUCTING PATHS FOR ENHANCING HEAT DISSIPATION AND WRAPPING AROUND CAP FOR IMPROVING INTEGRITY AND RELIABILITY, issued to Teng, et al. on Jan. 20, 1998, there is described an electronic package which includes a chip cap for covering and protecting an integrated chip therein. The chip cap further forms a concave step near a lower edge of the cap for wrapping around the edge of the package's adapter board for increasing the contact areas between the cap and the board and for attaching the cap to the board. The chip cap comprise thermal conductive materials and the chip cap further includes a heat sink for dissipating heat generated from the chip. The adapter board further includes a plurality of connecting vias and a plurality of conductive metal balls forming a ball grid array (BGA) underneath the adapter board. The chip is in electrical and thermal contact with the BGA by filling the connection vias with conductive materials. A printed circuit board is used for supporting and receiving the adapter board thereon.

In U.S. Pat. No. 5,786,635 for ELECTRONIC PACKAGE WITH COMPRESSIBLE HEATSINK STRUCTURE, issued to Alcoe, et al. on Jul. 28, 1998, there is described an electronic package wherein an electronic device (e.g., chip) on a circuitized substrate of the package is thermally coupled to a heatsink in a separable manner using a plurality of compressible, thermally conductive members (e.g., solder balls). These members are compressed and permanently deformed as part of the thermal coupling.

In U.S. Pat. No. 6,058,015 for ELECTRONIC PACKAGES AND A METHOD TO IMPROVE THERMAL PERFORMANCE OF ELECTRONIC PACKAGES, issued to Sammakia, et al. on May 2, 2000, there is described an electronic package incorporating a heat-generating element which is thermally coupled to a heat-sinking member, through the utilization of a predetermined thermally conductive material, and wherein all of these components are placed in compression during package operation so as to improve the thermal performance of the electronic package. A method is set forth of improving the thermal performance of an electronic package through the intermediary of compressive forces being generated between the package components during package operation.

In U.S. Pat. No. 6,156,484 for GRAY SCALE ETCHING FOR THIN FLEXIBLE INTERPOSER, issued to Bassous, et al. on Dec. 5, 2000, there is described a sculpted probe pad and a gray scale etching process for making arrays of such probe pads on a thin flexible interposer for testing the electrical integrity of microelectronic devices at terminal metallurgy. Also used in the etching process is a novel fixture for holding the substrate and a novel mask for one-step photolithographic exposure. The result of the invention is an array of test probes of preselected uniform topography, which make ohmic contact at all points to be tested simultaneously and nondestructively.

In U.S. Pat. No. 6,395,998 for ELECTRONIC PACKAGE HAVING AN ADHESIVE RETAINING CAVITY, issued to Farquhar, et al. on May 28, 2002, there is described an electronic package and method of making the electronic package. An opening in a thermally conductive member of the electronic package is formed to substantially prevent adhesive which can bleed from under a substrate mounted and secured on the thermally conductive member from contacting a portion of the thermally conductive member upon which an electrical element will be mounted.

In U.S. Pat. No. 6,507,116 for ELECTRONIC PACKAGE AND METHOD OF FORMING, issued to Caletka, et al. on Jan. 14, 2003, there is described an electronic package and method of making same in which a thermally conductive member is in thermally conductive communication with a semiconductor chip encapsulated within a dielectric material that surrounds portions of a thermally conductive member, semiconductor chip, and a predefined portion of a circuitized substrate. The present invention's thermally conductive member includes two portions of different bending stiffness to assure reduced interfacial stresses between the semiconductor chip and the circuitized substrate.

In U.S. Pat. No. 6,562,662 for ELECTRONIC PACKAGE WITH BONDED STRUCTURE AND METHOD OF MAKING, issued to Shishido, et al. on May 13, 2003, there is described an electronic package comprising a semiconductor chip mounted on a substrate which is formed by bonding a structure which covers at least an outer surface of the semiconductor chip and has the same or about the same thermal expansion coefficient as the substrate to the semiconductor chip's side surface of the substrate. This reduces warp and deformation caused by temperature changes during package operation.

In U.S. Pat. No. 6,744,132 for MODULE WITH ADHESIVELY ATTACHED HEAT SINK, issued to Alcoe, et al. on Jun. 1, 2004, there is described a method and structure to adhesively couple a cover plate to a semiconductor device. A semiconductor device is electrically coupled to a substrate. A stiffener ring surrounding the semiconductor device is adhesively coupled to the substrate. A cover plate is adhesively coupled to both a top surface of the semiconductor device and a top surface of the stiffener ring using a first and second adhesive, respectively. The modulus of the first adhesive is less than the modulus of the second adhesive.

In U.S. Pat. No. 6,790,305 for METHOD AND STRUCTURE FOR SMALL PITCH Z-AXIS ELECTRICAL INTERCONNECTIONS, issued to Curcio, et al. on Sep. 14, 2004, there is described a method of providing interconnections with package structures using electrically conductive (and non-conductive) pastes.

In U.S. Pat. No. 6,992,896 for STACKED CHIP ELECTRONIC PACKAGE HAVING LAMINATE CARRIER AND METHOD OF MAKING SAME, issued to Fraley, et al. on Jan. 31, 2006, there is defined a multi-chip electronic package which utilizes an organic, laminate chip carrier and a pair of semiconductor chips positioned on an upper surface of the carrier in a stacked orientation. The organic, laminate chip carrier is comprised of a plurality of conductive planes and dielectric layers and couples one or both of the chips to underlying conductors on the bottom surface thereof. The carrier may include a high-speed portion to assure high-frequency connection between the semiconductor chips and may also include an internal capacitor and/or thermally conductive member for enhanced operational capabilities. The first chip, e.g., an ASIC chip, is solder bonded to the carrier while the second chip, e.g., a memory chip, is secured to the first chip's upper surface and coupled to the carrier using a plurality of wire-bond connections.

In U.S. Pat. No. 7,161,810 for STACKED CHIP ELECTRONIC PACKAGE HAVING LAMINATE CARRIER AND METHOD OF MAKING SAME, issued to Fraley et al. on Jan. 9, 2007, there is defined a multi-chip electronic package which utilizes an organic, laminate chip carrier and a pair of semiconductor chips positioned on an upper surface of the carrier in a stacked orientation. The organic, laminate chip carrier is comprised of a plurality of conductive planes and dielectric layers and couples one or both of the chips to underlying conductors on the bottom surface thereof. The carrier may include a high-speed portion to assure high-frequency connection between the semiconductor chips and may also include an internal capacitor and/or thermally conductive member for enhanced operational capabilities. The first chip, e.g., an ASIC chip, is solder bonded to the carrier while the second chip, e.g., a memory chip, is secured to the first chip's upper surface and coupled to the carrier using a plurality of wirebond connections.

In U.S. Pat. No. 7,511,518 for METHOD OF MAKING AN INTERPOSER, issued to Egitto, et al. on Mar. 31, 2009, there is defined a method of making an interposer in which at least two dielectric layers are bonded to each other to sandwich a plurality of conductors there-between. The conductors each electrically couple a respective pair of opposed electrical contacts which are formed within and protrude from openings which are also formed within the dielectric layers as part of this method. The resulting interposer is ideally suited for use as part of a test apparatus to interconnect highly dense patterns of solder ball contacts of a semiconductor chip to lesser dense arrays of contacts on the apparatus's printed circuit board.

In U.S. Pat. No. 7,629,541 for HIGH SPEED INTERPOSER, issued to Caletka, et al. on Dec. 8, 2009, there is defined a high speed interposer which includes a substrate having alternating dielectric and conductive layers which form a substrate, openings which extend from one opposing surface of the substrate to a second opposing surface, conductive members positioned within the openings and also extending from surface to surface (and beyond, in some embodiments), and a plurality of shielding members positioned substantially around the conductive members to provide shielding therefore during the passage of high frequency signals through the conductive members.

In U.S. Pat. No. 7,629,684 for ADJUSTABLE THICKNESS THERMAL INTERPOSER AND ELECTRONIC PACKAGE UTILIZING SAME, issued to Alcoe, et al. on Dec. 8, 2009, there is defined an electronic package which includes a substrate (e.g., a chip carrier substrate or a PCB), an electronic component (e.g., a semiconductor chip), a heatsink and a thermal interposer for effectively transferring heat from the chip to the heatsink. The interposer includes a compressible, resilient member (e.g., an elastomeric pad) and a plurality of thin, metallic sheets (e.g., copper foils) and the thickness thereof can be adjusted by altering the number of such foils.

The present invention represents a new and unique electronic package which utilizes first and second circuitized substrates that enclose at least one electronic component which in turn is substantially surrounded by an interposer located between both substrates. The invention affords many advantages over packages such as those described above, as will be understood from a reading of this disclosure. It is believed that such a package, and a method of making such a package, would constitute significant advancements in the art.

### SUMMARY OF THE INVENTION

It is a primary object of the present invention to enhance the electronic package art.

It is a more particular object of the invention to provide an electronic package which will possess the many advantageous features defined herein and otherwise discernible from the instant teachings.

It is still another object of the invention to provide a method of making such a package which may be accomplished in a relatively facile manner and at relatively low cost in comparison to various known package manufacturing processes.

According to one embodiment of the invention, there is provided an electronic package comprising a base circuitized substrate including first and second opposing surfaces, each of these first and second opposing surfaces including a circuit thereon. The circuits include a plurality of electrical conductors. A cover circuitized substrate also includes first and second opposing surfaces. Each of these first and second opposing surfaces also includes a circuit thereon including a plurality of electrical conductors and an interposer positioned between the base and cover circuitized substrates. The interposer electrically interconnects selected ones of the electrical conductors of the circuit on the first opposing surface with corresponding selected ones of the electrical conductors of the circuit on the second opposing surface of the cover circuitized substrate. The interposer includes an opening therein. At least one electrical component is positioned within the interposer opening and is electrically coupled to selected ones of the electrical conductors on said first opposing surface other than those selected electrical conductors being electrically interconnected to the electrical conductors on said second opposing surface of the cover circuitized substrate. The cover circuitized substrate provides a cover for the electrical component.

According to another embodiment of the invention, there is provided a method of making an electronic package which comprises providing a base circuitized substrate including first and second opposing surfaces. A circuit including a plurality of electrical conductors on each of the opposing surfaces is formed. A cover circuitized substrate is provided that includes first and second opposing surfaces. A circuit including a plurality of electrical conductors on each of these opposing surfaces of the cover circuitized substrate is formed. An interposer including an opening therein is positioned between the base and cover circuitized substrates and electrically interconnects selected ones of the electrical conductors on the first opposing surface of the base circuitized substrate with corresponding selected ones of electrical conductors on the second opposing surface of the cover circuitized substrate using said interposer. At least one electrical component is positioned within the interposer opening, electrically coupling the electrical component to selected ones of the electrical conductors on said first opposing surface of the base circuitized substrate other than those selected electrical conductors being electrically interconnected to the selected electrical conductors on the second opposing surface of the cover circuitized substrate. The cover circuitized substrate is positioned substantially over the electrical component to substantially cover this electrical component.

### BRIEF DESCRIPTION OF THE DRAWINGS

Various objects, features, and attendant advantages of the present invention will become more fully appreciated as the same becomes better understood when considered in conjunction with the accompanying drawings, in which like reference characters designate the same or similar parts throughout the several views, and wherein:

FIG. 1 illustrates the first step of forming an electronic package in accordance with one embodiment of the present invention;

FIG. 2 illustrates the substrate of FIG. 1 having components attached;

FIG. 3 illustrates the substrate of FIG. 2 having an interposer positioned thereon;

FIG. 4 illustrates the electronic package of the present invention;

FIGS. 5a and 5b illustrate an electrical connection that may be utilized in the present invention; and

FIG. 6 illustrates alternative interconnections that may be utilized in the present invention.

### DETAILED DESCRIPTION OF THE PREFERRED EMBODIMENT

For a better understanding of the present invention, together with other and further objects, advantages and capabilities thereof, reference is made to the following disclosure and appended claims in connection with the above-described drawings. It is understood that like numerals will be used to indicate like elements from drawing figure to drawing figure.

### DEFINITIONS

The following terms will be used herein and are understood to have the meanings associated therewith.

By the term “circuit” as used herein is meant a pattern of electrical conductors, selected ones of these electrical conductors being electrically interconnected by circuit lines (also referred to in the industry as “traces”). Typically, such circuits are comprised of copper or copper alloys, but this invention is not limited to these materials.

By the term “circuitized substrate” as used herein is meant to define a structure including at least one dielectric layer having first and second opposing surfaces each having thereon at least one circuit, these circuits being interconnected through the dielectric layer in a predetermined manner. Examples of dielectric materials suitable for use in such structures include fiberglass-reinforced or non-reinforced epoxy resins (sometimes referred to simply as FR4 material, meaning its Flame Retardant rating), poly-tetrafluoroethylene (Teflon), polyimides, polyamides, cyanate resins, photoimageable materials, and other like materials, or combinations thereof. Examples of electrically conductive materials for the circuit layers include copper or copper alloy. If the dielectric is a photoimageable material, it is photoimaged or photopatterned, and developed to reveal the desired circuit pattern, including the desired opening(s) as defined herein, if required. The dielectric material may be curtain coated or screen applied, or it may be supplied as a dry film or in other sheet form.

By the term “electronic package” as used herein is meant to include at least one and possibly more such circuitized substrates (in the case of the present invention, at least two are used) and at least one electrical component (defined below) mounted on and electrically coupled to a substrate.

By the term “electrical component” as used herein is meant components such as semiconductor chips including stacked chips, resistors, capacitors, inductors, electronic packages including stacked packages, and the like, which are adapted for being positioned on and electrically coupled to the external conductors of the circuits of such substrates, and electrically coupled to other components (if utilized). The circuitized substrates taught herein are readily adaptable for having one or more such electrical components positioned thereon and electrically coupled thereto.

By the term “high density” as used herein to define the pattern of electrical conductors of the substrate and electronic device circuitry is meant a pattern wherein the conductors each possess a maximum width within the range of from only about 0.2 mils to about 1.0 mil and are spaced apart from each other (at the nearest point of edges of adjacent conductor features) within the range of only about 0.2 mils to about 1.0 mil (as defined herein, a mil is equal to 0.001 inch).

By the term “high speed” as used herein to define the substrate signal speed capabilities is understood to mean signals within a frequency range of from about 3.0 to about 10.0 Gigabits Per Second (GPS) and possibly even faster. The circuitized substrates of the instant invention are capable of operating at such high frequencies if desired.

By the term “information handling system” as used herein is meant to define any instrumentality or aggregate of instrumentalities primarily designed to compute, classify, process, transmit, receive, retrieve, originate, switch, store, display, manifest, measure, detect, record, reproduce, handle or utilize any form of information, intelligence or data for business, scientific, control or other purposes. Examples include personal computers and larger processors such as computer servers and mainframes. Such products are well known in the art and are also known to include electronic packages including PCBs and chip carriers and other forms of circuitized substrates as part thereof, some including several such packages depending on the operational requirements thereof.

By the term “interposer” as used herein is meant to include a structure capable of electrically interconnecting arrays of electrical conductors on two opposing circuitized substrates using extremely small conductive elements such as very small solder balls, solder paste or conductive paste, as well as by using conductive thru-holes as defined herein. Such an interposer, as defined herein, includes at least one dielectric layer (and may include many) and at least two external conductive circuit layers (and possibly one or more internal conductive circuit layers) wherein the layers each include a high density array of contact locations. Examples of dielectric materials include such materials as fiberglass-reinforced epoxy resins (some referred to as “FR-4” dielectric materials in the art), such reinforced resins having inorganic particles (e.g., silica) therein as well as epoxy resins including inorganic particles (e.g., silica) for the purpose of controlling the coefficient of thermal expansion (CTE) of the dielectric material, polytetrafluoroethylene (e.g., Teflon), including poytetrafluoroethylene filled with inorganic particles (e.g., silica) as a means of controlling the coefficient of thermal expansion of the dielectric material, polyimides (e.g., Kapton), fiberglass-reinforced polyimides, polyamides, cyanate resins, polyphenylene ether resins, fiberglass-reinforced polyphenylene ether resins, fiberglass-reinforced polyphenylene ether resins filled with inorganic particles (e.g., silica), aramid fiber-reinforced resins, liquid crystal polymers, photo-imageable materials, and other like materials. If the dielectric materials for the interposer are of a photo-imageable material, this material may be photo-imaged (or photo-patterned), and developed to reveal the desired pattern of openings. The dielectric material may be curtain-coated, spin-coated or screen-applied, or it may be supplied as dry film.

By the term “Kapton” as used herein is meant a polyimide material currently available from E.I. duPont deNemours & Company (DuPont) of Wilmington, Del., and sold under this product name.

By the term “Teflon” as used herein is meant a polytetrafluoroethylene material currently available from duPont and sold under this product name.

By the term “thin” as used herein to define a dielectric layer for use in the interposer of the invention is meant a thickness within the range of from only about 0.5 mils to about three mils, a mil being equal to 0.001 inch.

By the term “thru-hole” as used herein to define a conductive structure within an interposer as defined herein is meant to include three different types of electrically conductive holes. It is known in multilayered PCBs and chip carriers to provide various conductive interconnections between various conductive layers of the PCB and carrier. For some applications, it is desired that electrical connection be made with almost if not all of the conductive layers. In such a case, thru-holes are typically provided through the entire thickness of the board, in which case these are often also referred to as “plated thru holes” or PTHs. For other applications, it is often desired to also provide electrical connection between the circuitry on one face of the substrate to a depth of only one or more of the inner circuit layers. These are referred to as “blind vias,” which pass only part way through or into the substrate. In still another case, such multilayered substrates often require internal connections (“vias”) which are located entirely within the substrate and covered by external layering, including both dielectric and conductive. Such internal “vias,” also referred to as “buried vias,” may be formed within a first circuitized substrate which is then bonded to other substrates and/or dielectric and/or conductive layers to form the final, multilayered embodiment. Therefore, for purposes of this application, the term “thru hole” is meant to include all three types of such electrically conductive openings.

As defined herein and also understood from the description, this invention possesses many advantageous features which are considered highly desirable in the electronic packaging industry. Among these of course include a small, compact design which maximizes space, assures effective heat removal and is also able to assure maximum capacity, including the provision of enabling high speed signal passage therethrough. Rework is possible, if needed, without significant expenditure, thereby facilitating the removal and replacement of defective parts, including semiconductor devices. The resulting package design as taught herein is of relatively stiff design, possibly eliminating the need for an additional stiffener or the like as required in many known packages. The design also serves to reduce destructive stresses which may build up during package operation, thereby also substantially preventing highly undesirable warping. Significantly, the construction is of relatively simple design to thereby reduce manufacturing costs. Still further, the package is adaptable to using a variety of electrical components, including of course, semiconductor chips, but also embedded resistors and capacitors. Other features are discernible from the following description and reference to the corresponding drawing figures.

In FIG. 1, there is shown the first step of forming an electronic package according to one embodiment of this invention. More specifically, a first circuitized substrate 21 is provided, this substrate 21 including at least one thin dielectric layer 23 having first and second (in FIG. 1, upper and lower) surfaces 25 and 27. In one embodiment, substrate 21 may include more than one dielectric layer and include one or more circuit patterns. One element 29, a pad, of one circuit pattern is shown in FIG. 1 in phantom to represent this possibility. The dielectric layer(s) may comprise one of the above defined dielectric materials, depending on final product application requirements, e.g., electrical, mechanical, and thermal. Among the most commonly used materials include the afore-defined epoxy-based dielectrics, and for even higher performance applications, the afore-defined PTFE-based dielectrics, LCP, or dielectric materials formed from polyphenylene ether resins may be utilized. Any internal circuit patterns as defined above are formed prior to lamination of the individual dielectric layers, each having such a pattern thereon with other such layer-circuit pattern structures to form the multilayered substrate. Such circuit patterns, including the pads and any desired connecting lines or traces (not shown in FIG. 1), are preferably of copper or copper alloy and are formed on the respective dielectric layer using conventional photolithographic processing known in the substrate art. This (formation process, materials) is also true for the external patterns in FIG. 1, further defined below.

As also seen in FIG. 1, substrate 21 further includes such external circuit patterns 31 and 33 on the first and second opposing surfaces 25 and 27, respectively, these patterns also of conventional metallurgy and formed using known photolithographic processing. As defined herein, the first pattern 31 of conductors is adapted to have at least one electrical component, i.e., a semiconductor chip, coupled thereto when the component is mounted on the first surface 25. (Chip 41 is shown in FIG. 2.) In one embodiment, pattern 31 includes conductors positioned in at least two different density patterns. Specifically, those conductors 35 intended to be coupled to corresponding conductors on the chip 41 are of a high density pattern, while conductors 37 positioned on surface 25 externally of the chip conductors 31 may be of a lesser density, spaced greater distances apart and possibly of larger configuration. By a lesser density in this embodiment may mean a maximum width of conductor 37 within the range of from only about one mil to about 10 mils, with these spaced apart from each other within the range of only about one mil to about 10 mils. In this embodiment, copper or copper alloy conductors may be used. If added components, i.e., resistor 39 (FIG. 2) are also to be positioned on and coupled to the upper surface 25 pattern, similar or even different configuration conductors may be used, depending on the associated density pattern of the respective added component. The upper pattern is therefore not limited to the specific density orientations shown in FIG. 1.

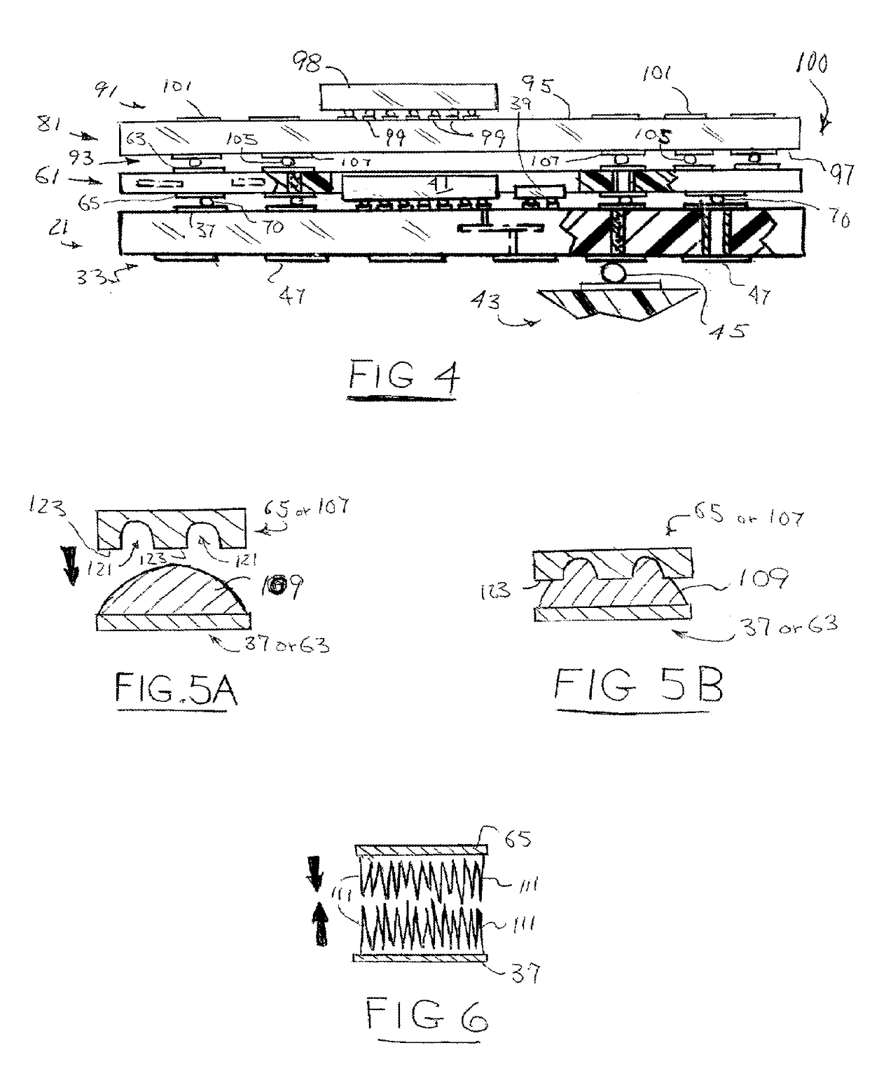

Lower circuit pattern 33 is in turn adapted for being coupled to a larger hosting circuitized substrate such as a PCB 43 (shown in FIG. 4), i.e., using solder balls 45 (also shown in FIG. 4). The conductors 47 which comprise pattern 33 may all be of a lesser density (including one similar to the pattern of conductors 37) than that of opposing conductors 35, depending on the associated pattern of conductors of the hosting substrate 43. These pattern differences represent an important feature of the invention because of the adaptability of the resulting product to meet many stringent packaging requirements. Formation of both patterns 31 and 33 may be accomplished simultaneously, using the aforementioned photolithographic or similar processing, or said patterns may be individually formed.

Conductors 37 and 47 may be interconnected using different means, including the conventional plated thru hole approach (“PTH” in FIG. 1) defined above, use of electrically conductive paste 51 within an interconnecting opening, or a combination of the two (paste within a PTH). Other means known in the art are also possible and this invention is not limited to the two embodiments shown in the drawings. As further seen in FIG. 1, it is also possible to connect selected ones of the upper or lower conductors to one or more interim circuits as represented by the internal conductor 29. Many combinations of such connections are well within the scope of this invention.

First substrate 21 may thus be referred to as a base substrate for the electronic package eventually being formed herein, since it hosts one or more of the electrical components, i.e., resistor 39, chip 41, to be retained within the package body (defined in greater detail below) and is also adapted for being positioned on the hosting substrate to couple the completed package thereto. Understandably, the base substrate as formed herein is not coupled to such a hosting PCB until the package has been so completely formed. When so assembled, the package and hosting substrate may form part of an information handling system.

In FIG. 2, substrate 21 is shown having components 39 and 41 thereon, both electrically coupled to the designated conductors of the substrate. Substrate 21 is thus in its final form prior to subsequent bonding to other parts of this invention described hereinbelow.

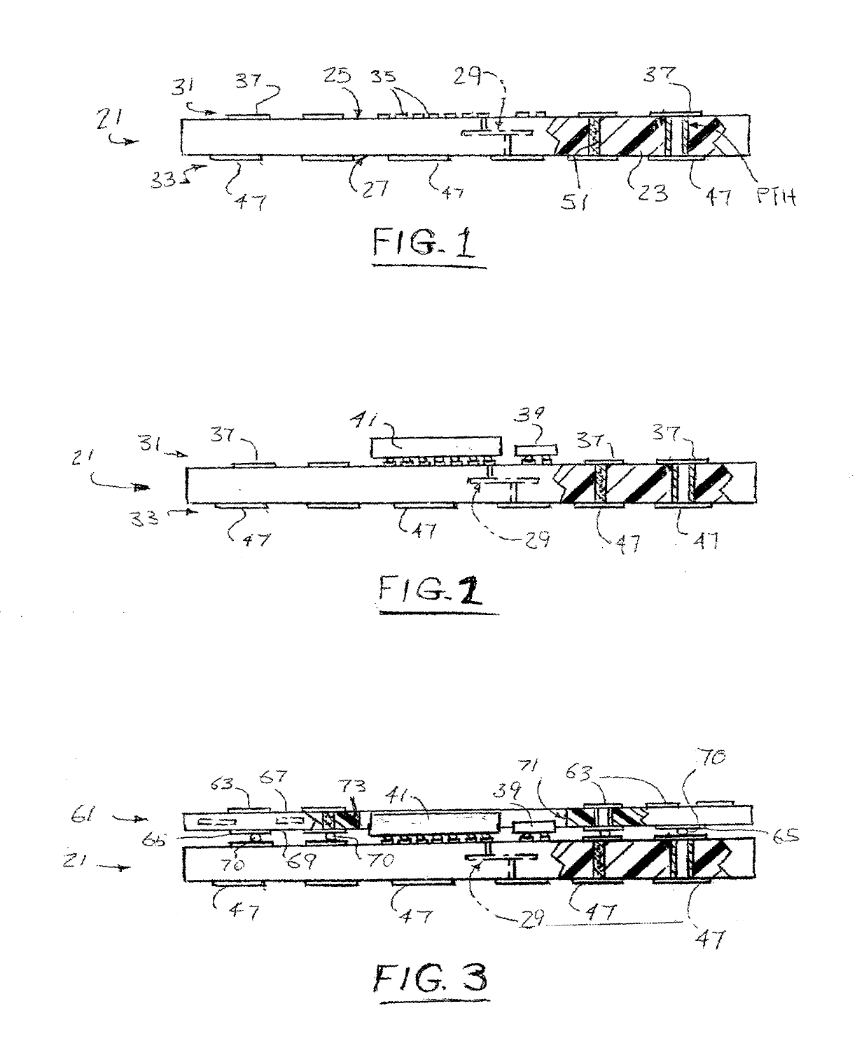

In the next step, shown in FIG. 3, an interposer 61 is positioned on substrate 21 and electrically coupled thereto. Interposer 61 represents a significant aspect of this invention for the reasons explained herein and discernible from these teachings. In one key aspect, interposer 61 essentially represents a second of three circuitized substrates which will form the final package of this invention. In addition to affording protection to the internally housed components such as elements 39 and 41, it also provides additional circuitry and, if desired, added components, which in turn expand the operational capabilities of the final package. That is, interposer 61 includes upper and lower patterns of conductors 63 and 65, respectively, on respective upper and lower surfaces 67 and 69 of at least one dielectric layer 73. Interposer 61 may also include internal components (not shown) such as embedded capacitors or resistors, as part of its make-up, adding further operational capabilities to this invention.

As with substrate 21, the opposing conductors may be interconnected using known means such as PTHs and/or paste and/or combinations of the two, as well as using alternative coupling structures. The circuits may be of copper or copper alloy and formed also using conventional photolithographic processing known in the packaging art. The corresponding patterns of conductors 63 and 65 may also vary, depending on the corresponding pattern of conductors to which these conductors 63 and 65 are to be coupled. Equally significant, interposer 61 includes at least one opening 71 therein, which is designed to accommodate the components positioned therein. Opening 71 may be as large as needed for this purpose. It is also possible to include individual openings per component if desired. Only one opening 71 is shown herein for ease of explanation purposes.

Interposer 61 is preferably coupled to substrate 21 using solder elements, a preferred example being solder balls 70 of conventional compositions. This assures facile separation of the substrate and interposer should rework and/or component replacement be necessary, and thus represents another important feature of this invention. Interposer 61 includes at least one dielectric layer 73, which may be of one of the above described dielectric materials, one desirable such material being Teflon. The layer or layers may also preferably be thin in construction. For added rigidity, it is also possible to use a ceramic material known in the art of electronic packaging. Polymer dielectric materials are preferred, however, for ease of manufacture and because so many have proven very successful in such packaging compared to the earlier ceramics. Regardless of material, the interposer defined herein may further eliminate the need for an added stiffener or the like, as are often required in electronic package structures known today.

Solder balls 70, as stated, may be of conventional composition, as may be those used to couple components 39 and 41 to substrate 21. In one embodiment, for example, the solder balls 70 may be of one tin-lead composition (e.g., 63:37), while those used to couple components 39 and 41 may be of a different tin-lead composition (e.g., 10:90), so as to afford different melting points during processing, such as removal of selected parts of the final package for rework and/or replacement without damage to the other. Many different combinations are possible and the invention is not limited to these particular compositions. Lead-free solders, such as tin-gold-copper alloy, may also be utilized. Yet an even different solder composition may be used for solder balls 45 used to couple substrate 21 to its hosting substrate (FIG. 4).

In FIG. 4, there is shown the embodiment of FIG. 3, albeit on a slightly larger scale for better illustration, wherein a cover circuitized substrate 81 is positioned above the substrate 21-interposer 61 pair. As such, the three structures shown bonded together in FIG. 4 now form an electronic package 100. Substrate 81 is considered a cover substrate because it serves as a cover for package 100 to cover and protect both the interposer 61 and, importantly, the components and circuitry of base substrate 21 located within the interposer opening 71 and thus surrounded by the sidewalls that define the opening. In combination with the base substrate 21 and surrounding interposer 61, substrate 81 protects these enclosed elements from potentially harsh environmental conditions to which the final package may be exposed. The total of the heights of interposer 61 and any associated joining metallurgy (in this case, solder elements 70 and 105) must be greater than the height of the thickest assembled component (including the component's joining metallurgy) in opening 71.

Cover circuitized substrate 81 may be similar to corresponding base circuitized substrate 21 in both material and dimensional aspects. That is, it may include one or more thin dielectric layers or one or more internal circuit patterns. Like substrate 21, substrate 81 includes opposing external circuit patterns 91 and 93 on the first and second opposing surfaces 95 and 97, respectively, these patterns also of conventional metallurgy and formed using known photolithographic processing. As with substrate 21, the first pattern 91 of conductors is adapted to have at least one electrical component, a semiconductor chip 98, coupled thereto when the component is mounted on first surface 95.

In one embodiment, pattern 91, like pattern 31 of substrate 21, includes conductors positioned in at least two different density patterns. Specifically, those conductors 99 intended to be coupled to corresponding conductors on chip 98 are of a high density pattern, while those conductors 101 positioned on surface 95 externally of the chip conductors may be, and preferably are, of a lesser density. A lesser density in this embodiment may mean a maximum conductor 101 width within the range of from only about one mil to about 10 mils, with these spaced apart from each other within the range of only about one mil to about 10 mils. In this embodiment, copper or copper alloy conductors may be used. If added components, i.e., resistor (not shown) are also to be positioned on and coupled to the upper surface 95 pattern 91, similar or even different configuration conductors may be used, depending on the associated density pattern of the respective added component(s). The upper pattern, therefore, is not limited to the specific density orientations shown in FIG. 4.

The lesser density pattern of conductors 107 of lower circuit pattern 93 are in turn adapted for being coupled to interposer 61, using solder balls 105. Some of the conductors 107 that comprise pattern 93 may be of such a lesser density than that of opposing conductors 101, of a substantially similar density pattern as conductors 101, while selected ones of these conductors 107 are of a pattern similar to that of conductors 63 of the hosting interposer 61, so as to assure sound couplings between respective pairs of conductors 107 and 63. These pattern differences, like those between substrate 21 and interposer 61, represent a further important feature of the invention because of the adaptability of the resulting product to meet many stringent packaging requirements from customers. Formation of patterns 91 and 93 may be accomplished simultaneously, using the aforementioned photolithographic or similar processing, or individually.

Conductors 101 and 107 may be interconnected using different means, including the means depicted in FIG. 1, e.g., plated thru holes (PTH), use of electrically conductive paste within an interconnecting opening, or a combination of the two. Other means known in the art are also possible and this invention is not limited to these two embodiments. As with substrate 21, and as mentioned above (if the substrate has one or more internal circuit patterns), it is also possible to connect selected ones of the upper or lower conductors to one or more such interim circuits. Many combinations of such connections are well within the scope of this invention.

Surprisingly, the addition of a cover substrate 81 to cover and thereby help to enclose the internal chip(s) 41 still enables sufficient removal of heat generated by the chip during package operation. Significantly, such heat removal is achieved without adversely affecting the operation of the upper chip 98, located directly above chip 41. As mentioned above, effective heat removal is essential for the successful operation of any electronic package. The invention as defined herein is able to provide these features despite the very close positioning of the circuitized substrates (including considering interim interposer 61 as also functioning as a circuitized substrate) and the close proximity of heat-generating components which form part of the package structure.

The three individual structures (base substrate 21, interposer 61 and cover substrate 81) may also be bonded together in a single step to form the electronic package 100. In addition, the three individual structures can be tested prior to joining, improving stacked package yield by selection of only good individual structures, and/or allowing rework. As stated above, when the three individual structures (base substrate 21, interposer 61 and cover substrate 81) are bonded together to form electronic package 100, the package may now be positioned on and bonded to the larger hosting substrate 43.

FIGS. 5a and 5b represent one type of electrical connection which may be utilized in this invention, in addition to or in place of, the solder ball couplings defined herein. In FIG. 5a, a solder element 109 initially positioned on one of the conductors 37 or 63, already formed on the respective substrate (including interposer 61) is aligned with a corresponding conductor 65 or 107, respectively, which is of sculpted configuration. By the term “sculpted” as used herein is meant a final external configuration of a metallic conductor such as may be formed using differential gray scale etching. One known example of such a configuration, similar to that shown in FIGS. 5a and 5b, is defined in the aforementioned U.S. Pat. No. 7,511,518 (FIG. 1). In this patent, reference is made to U.S. Pat. No. 6,156,484, cited above, which discusses in detail such an etching process. As described, various designated surface areas of the conductor are etched at different rates to form the final configuration shown. In this example, the etched conductor 65 or 107 includes two recesses 121, and at least three flats 123. These recesses may be in groove form or simply cylindrical. Many different configurations are of course possible, and this invention is not limited to the FIGS. 5a and 5b embodiment. This conductor, as understood, is capable of penetrating, albeit perhaps only partially, the surface of a contact such as a solder ball, as seen in FIG. 5b, to thereby form a solid connection. Significantly, this connection may be separated, e.g., by applying heat sufficient to melt the solder 109 slightly but not harm other package structures, should rework or replacement be necessary.

In addition to sculpted and solder interconnections, many other types of interconnections are possible with the invention. Other examples include flat-to-flat (both facing surfaces are flat) conductor pairings, sculpted to sculpted, solder element to flat, and so forth. In most embodiments, it is intended that the formed interconnections be separable for the reasons stated. This is not limiting of the invention, however, since permanent, non-separable connections may be formed, e.g., electrically conductive adhesive in the interposer PTH(s) to conductors on the cover and base substrates, albeit such connections would not afford the ease of rework and/or replacement provided by separable connections.

One of the preferred forms of such alternative interconnections is shown in FIG. 6. Specifically, two opposing conductors 37 and 65 are each plated with a plurality of dendritic elements 111 by a method such as electroplating. Preferred materials for elements 111 are metals or alloys of metals selected from the group consisting essentially of palladium, nickel, gold, platinum, rhodium, ruthenium, irridium and osmium. The electroplating of such dendritic elements may, for example, be accomplished by one or methods known in the art. The metal palladium has proven to provide a particularly favorable combination of electrical, mechanical and chemical properties (high electrical conductivity, ductility, yield strength and corrosion resistance) for the function of such elements when electroplated at temperatures near 30 degrees Celsius (C), and current densities near 60 milli-amperes per square centimeter, e.g., from an aqueous ammonia bath containing 15 milli-molar palladium tetrammine chloride and 5 molar ammonium chloride, adjusted to a pH of 9 to 9.2. Preferably, these formed elements are then over-plated at current densities of 10 milli-amperes per square centimeter, in a bath of the same composition given above, except that the concentration of palladium is 150 milli-molar in this second bath. Significantly, this over-plating with palladium metal strengthens the formed dendritic elements. An example of how such plating is performed in described in the aforementioned U.S. Pat. No. 5,237,743. As shown, the formed dendritic elements project predominantly in a direction perpendicular to the corresponding flat surface of the conductor on which these are “grown.” Such offsetting orientations are particularly desired to provide enhanced connection between these elements, as well as assuring desirable separable connections as mentioned above.

In one example of the invention shown in FIG. 4, base substrate 21 may have an overall thickness (outer surface of top conductor to outer surface of lower conductor) of from about 2 mils to about 500 mils, interposer 61 an overall thickness of about 1 mil to about 80 mils, and cover substrate 81 of an overall thickness of about 2 mils to about 500 mils, giving the assembled electronic package of FIG. 4 a total thickness or height of only from about 5 mils to about 1080 mils. This very thin overall profile represents a significant aspect of the invention.

Thus there has been shown and described a new and unique electronic package which provides several advantageous features taught herein and otherwise discernible from these teachings. Among these include compactness and simplicity of design, safe and effective component heat removal, high speed signal passage therethrough, and rework and/or replacement of key elements if necessary. Additionally, use of an interposer of the type taught assures a relatively stiff design, possibly eliminating need for any additional stiffener or stiffening structure. The final package further assures reduced stresses which may build up during package operation and even possibly result in destruction thereof from highly undesirable package warping. Still further, the package is adaptable to using a variety of electrical components, including of course, semiconductor chips, but also embedded resistors and capacitors.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. An electronic package comprising:
a base circuitized substrate including first and second opposing surfaces, each of said first and second opposing surfaces including a first circuit thereon including a plurality of electrical conductors;
a cover circuitized substrate including first and second opposing surfaces, each of said first and second opposing surfaces including a second circuit thereon including a plurality of electrical conductors;
an interposer positioned substantially between said base and cover circuitized substrates, said interposer electrically interconnecting selected ones of said electrical conductors of said first circuit with corresponding selected ones of said electrical conductors of said second circuit, said interposer including an opening therein;
at least one electrical component positioned within said opening of said interposer and electrically coupled to selected ones of said electrical conductors of said first circuit other than said selected ones of said electrical conductors of said first circuit being electrically interconnected to said selected electrical conductors of said second circuit by said interposer, said cover circuitized substrate providing a cover for said at least one electrical component.

2. The electronic package of claim 1, further including at least one additional electrical component positioned on said first opposing surface of said cover circuitized substrate and electrically coupled to said second circuit thereon.

3. The electronic package of claim 2, wherein said at least one electrical component positioned within said opening of said interposer and said at least one additional electrical component positioned on said first opposing surface of said cover circuitized substrate each comprises a semiconductor device.

4. The electronic package of claim 1, wherein said interposer includes at least one dielectric layer having first and second opposing surfaces and a plurality of conductive members located substantially within said at least one dielectric layer, selected ones of said conductive members electrically interconnecting selected ones of said electrical conductors of said first circuit with corresponding selected ones of said electrical conductors of said second circuit.

5. The electronic package of claim 4, further including first and second pluralities of conductive pads located on said first and second opposing surfaces of said at least one dielectric layer, selected ones of said plurality of conductive members positioned substantially within said at least one dielectric layer interconnecting corresponding pairs of said selected ones of said first and second pluralities of conductive pads located on respectively said first and second opposing surfaces of said at least one dielectric layer.

6. The electronic package of claim 5, further including a first plurality of solder elements, selected ones of said first plurality of solder elements electrically coupling corresponding selected ones of said first plurality of conductive pads located on said first opposing surface of said at least one dielectric layer of said interposer with corresponding selected ones of said plurality of electrical conductors of said circuit on said second opposing surface of said cover circuitized substrate.

7. The electronic package of claim 6, further including a second plurality of solder elements, selected ones of said second plurality of solder elements electrically coupling corresponding selected ones of said second plurality of conductive pads located on said second opposing surface of said at least one dielectric layer of said interposer with corresponding selected ones of said plurality of electrical conductors of said circuit on said first opposing surface of said base circuitized substrate.

8. The electronic package of claim 4, wherein said selected ones of said conductive members each comprises a plated through hole.

9. The electronic package of claim 4, wherein said selected ones of said conductive members each comprises a quantity of electrically conductive paste.

10. The electronic package of claim 1, wherein said plurality of electrical conductors of said circuit on said first opposing surface of said base circuitized substrate form a high density pattern of said electrical conductors.

11. A method of making an electronic package, said method comprising:
providing a base circuitized substrate including first and second opposing surfaces;
forming a first circuit including a plurality of electrical conductors on each of said first and second opposing surfaces of said base circuitized substrate;
providing a cover circuitized substrate including first and second opposing surfaces;
forming a second circuit including a plurality of electrical conductors on each of said first and second opposing surfaces of said cover circuitized substrate;
positioning an interposer including an opening therein between said base and cover circuitized substrates and electrically interconnecting selected ones of said electrical conductors of said first circuit with corresponding selected ones of said electrical conductors of said second circuit using said interposer;
positioning at least one electrical component within said opening of said interposer;
electrically coupling said at least one electrical component to selected ones of said electrical conductors of said first circuit other than said selected ones of said electrical conductors of said first circuit being electrically interconnected to said selected electrical conductors of said second circuit; and
positioning said cover circuitized substrate substantially over said at least one electrical component to substantially cover said at least one electrical component.

12. The method of claim 11, further including positioning at least one additional electrical component on said first opposing surface of said cover circuitized substrate and electrically coupling said at least one additional electrical component to said second circuit.

13. The method of claim 11, further including providing a plurality of conductive members within said interposer, said conductive members providing electrical interconnecting of said selected ones of said electrical conductors of said first circuit with said corresponding selected ones of said electrical conductors of said second circuit.

14. The method of claim 13, further including forming first and second pluralities of conductive pads on first and second opposing surfaces of said interposer such that selected ones of said plurality of conductive members positioned within said interposer electrically interconnect corresponding pairs of said selected ones of said first and second pluralities of conductive pads located on said first and second opposing surfaces of said interposer.

15. The method of claim 14, further including providing a first plurality of solder elements and electrically coupling corresponding selected ones of said first plurality of conductive pads located on said first opposing surface of said interposer with corresponding selected ones of said plurality of electrical conductors of said circuit on said second opposing surface of said cover circuitized substrate using said first plurality of said solder elements.

16. The method of claim 15, further including providing a second plurality of solder elements and electrically coupling corresponding selected ones of said second plurality of conductive pads located on said second opposing surface of said interposer with corresponding selected ones of said plurality of electrical conductors of said first circuit using said second plurality of said solder elements.

17. The method of claim 11, wherein said electrically coupling said at least one electrical component to said selected ones of said electrical conductors of said first circuit other than said selected ones of said electrical conductors of said first circuit being electrically interconnected to said selected electrical conductors of said second circuit is accomplished using a plurality of solder elements.
